(19) United States
(12) Patent Application Publication
(10) Pub. No.: US 2024/0230847 A1
(43) Pub. Date: Jul. 11, 2024

(54) OPTICAL DEVICE AND METHOD OF MANUFACTURE

(71) Applicant: ams-OSRAM Asia Pacific Pte. Ltd., Singapore (SG)

(72) Inventors: Baiming GUO, Old Bridge, NJ (US); Jichi MA, Ithaca, NY (US); Qing WANG, Plainsboro, NJ (US); Guoyang XU, Newtown, PA (US)

(21) Appl. No.: 18/561,780

(22) PCT Filed: May 11, 2022
(86) PCT No.: PCT/SG2022/050304

§ 371 Date: Nov. 17, 2023

(30) Foreign Application Priority Data
May 18, 2021 (GB) 2107061.0

(51) Int. Cl. G01S 7/481; G01S 7/4865; G02B 3/00; H01S 5/183

(52) U.S. Cl. CPC G01S 7/4814; G01S 7/4865; G02B 3/0062; H01S 5/18302

(57) ABSTRACT

An optical device includes a plurality of radiation-emitting elements provided on a substrate, and a microlens arranged on the substrate such that a beam of radiation emitted by each of the plurality of radiation-emitting elements propagates through the microlens. Also disclosed is a method of manufacturing the optical device, and a time-of-flight sensor implementing the optical device.

### RELATED APPLICATIONS

This application is a US National Stage of International Application PCT/SG2022/050304, filed on 11 May 2022, which claims the benefit of United Kingdom Patent Application GB2107061.0, filed 18 May 2021. The above applications are hereby incorporated by reference in their entirety.

### FIELD OF DISCLOSURE

The present disclosure relates to the field of optical devices, and in particular to radiation-emitting optical devices suitable for use in devices such as proximity sensors and time-of-flight sensors.

### BACKGROUND

Many electronic devices, such as consumer electronic devices, comprise various optical devices to provide a rich and high-quality feature set. For example, personal electronic devices such as smartphones, tablet computers, wearables, games systems and the like, may comprise one or more optical devices for emitting and/or sensing radiation. For example, such optical devices may be configured as time-of-flight sensors, proximity sensors, illuminators, or the like.

An optical device may comprise a radiation-emitting element, such as a laser, and in some instances an associated optical element for modifying a beam of radiation emitted by the radiation-emitting element. In one such example, an optical element may comprise a lens configured to alter characteristics of the beam of radiation, for use in applications such as proximity sensing or time-of-flight measurements.

In known optical devices, lenses may be designed and fabricated as integrated parts of the optical device. A radiation beam output by a radiation-emitting element may pass through an associated lens, and thus be deflected by refraction in the lens. Each lens in such a device may be designed to output a beam of radiation from a radiation-emitting element at an individually determined angle, in accordance with a particular design specification. The angles may, for example, be determined by both a shape of the lenses and an offset of the lenses relative to associated radiation-emitting elements, and thus may define characteristics of far-field radiation emitted by the optical device.

However, such optical devices may be relatively large, and hence expensive to manufacture. For example, a relatively large area of lenses may be required to enable the device to provide far-field radiation having desired characteristics, thereby increasing costs of materials and reducing manufacturing efficiencies and throughput. Furthermore, an increased size may conflict with a recent industry trend, particular in personal electronic devices such as smartphones, towards miniaturization of electronic devices that incorporate such optical devices.

It is therefore desirable to provide an optical device that can be manufactured at low cost, exhibits a relatively small size compared to known devices, yet remains sufficiently accurate and reliable.

It is therefore an aim of at least one embodiment of at least one aspect of the present disclosure to obviate or at least mitigate at least one of the above identified shortcomings of the prior art.

### SUMMARY OF DISCLOSURE

The present disclosure relates to the field of optical devices, and in particular to radiation-emitting optical devices suitable for use in devices such as proximity sensors and time-of-flight sensors. The disclosure also relates to a method of manufacturing such optical devices.

According to a first aspect of the disclosure, there is provided an optical device comprising: a plurality of radiation-emitting elements provided on a substrate; and a microlens arranged on the substrate such that a beam of radiation emitted by each of the plurality of radiation-emitting elements propagates through the microlens, i.e. is directed through the microlens.

Advantageously, by having a plurality of radiation-emitting elements associated with a single microlens, an overall size of the optical device may be made smaller relative to an optical device wherein each radiation-emitting element may be associated with a single microlens.

Furthermore, by having a plurality of a radiation-emitting elements associated with a single microlens, a size of the microlens may be increased relative to the size of a microlens implemented on a similar sized optical device wherein each radiation-emitting element is associated with a single microlens. A larger microlens may advantageously simplify a manufacturing process.

Furthermore, by increasing a size, e.g. a diameter and radius of curvature, of the microlens, the microlens may be designed to exhibit a relatively long focal length, and hence may be manufactured with relatively large tolerances in the shape and dimensions of the microlens.

Advantageously by having a plurality of a radiation-emitting elements associated with a single microlens, a single microlens may be used to control multiple different fields of illumination, depending upon which of the plurality of radiation-emitting elements are configured to emit radiation, as described in more detail below.

Advantageously, by having a plurality of radiation-emitting elements associated with a single microlens and thereby potentially larger microlenses, an overall amount of microlenses required for an optical device may be reduced, simplifying manufacturing processes. Furthermore, on overall utilization of the available area of the optical device may be maximized.

The term ‘microlens’ used throughout this document will be understood to refer to a small lens, generally with a diameter of substantially less than a millimeter, and in some examples having a diameter as small as 10 micrometers or smaller. The terms microlens may also be known in the art as a lenslet′.

The term ‘substrate’ will be understood to include substrates, for example substrates of a Vertical Cavity Surface Emitting Lasers (VCSEL) chip, comprising one or more layers of material formed or otherwise deposited on a substrate or on any preceding layer or material formed on a substrate.

The microlens may be configured to deflect the beam of radiation emitted by each of the plurality of radiation-emitting elements at a different angle relative to the substrate, e.g. at a different angle relative to the substrate surface normal.

Advantageously, radiation-emitting elements associated with a single microlens may therefore be capable of collectively contributing to a larger field of illumination and/or multiple fields of illumination, depending upon which radiation-emitting elements are enabled, as described in more detail below.

The microlens may deflect the beam of radiation by refraction, wherein the angle of deflection may be determined by an angle of incidence of the beam of radiation with a surface of the microlens upon entering and/or exiting the microlens, and the ratio of a refractive index of the microlens to a material or fluid surrounding the microlens, as defined by Snell's law.

Each radiation-emitting element of the plurality of radiation-emitting elements may be disposed at a different offset relative to a center of the microlens.

Each radiation-emitting element of the plurality of radiation-emitting elements may be disposed at randomized offset relative to a center of the microlens. That is, in some examples the optical device may be implemented with a randomized emitter to microlens offset, wherein offsets between each radiation-emitting element and an associated microlens may be randomized.

That is, each radiation-emitting element may be laterally offset on a plane defined by the substrate. Therefore, radiation emitted by each radiation-emitting element may be incident upon a different portion of a microlens, and therefore an angle of deflection of each beam of radiation upon exiting the microlens may be selected accordingly to define a desired field of illumination.

The plurality of radiation-emitting elements may comprise vertical cavity surface emitting lasers (VCSELs) formed or mounted on the substrate.

The plurality of radiation-emitting elements may additionally or alternatively comprise diodes, such as laser diodes or light emitting diodes (LEDs).

The optical device may comprise a plurality of microlenses arranged on the substrate. Each microlens may have a corresponding plurality of radiation-emitting elements arranged on the substrate, such that a beam of radiation emitted by each radiation-emitting element propagates through a corresponding microlens.

In such example embodiments, the plurality of microlenses may be implemented as a microlens array. The plurality of microlenses may be implemented as a monolithic microlens array. The plurality of microlenses may be implemented as a monolithic microlens array on a VCSEL array chip, e.g. on the substrate. The plurality of microlenses may be directly etched into the substrate. In some examples, the microlens array may be provided as a tessellated pattern of microlenses. In some embodiments, a gap may be provided between adjacent microlenses. Each microlens may be substantially circular in plan view. Each microlens may be convex or concave. Each microlens may be implemented as a freeform lens, or diffractive Fresnell lens, or even metalens.

The plurality of microlenses may be arranged in a honeycomb arrangement. Each microlens may be substantially circular in plan view, and arranged in a hexagonal-packing arrangement.

Advantageously, by implementing a plurality of microlenses wherein each microlens has an associated plurality of radiation-emitting elements, all output beams of different deflection angles from the plurality of microlenses may collectively form a desired far field. That is, an overall illumination beam provided by the optical device may be formed by a combination of the multiple sub beams, each directed at a different angle of deflection.

Each radiation-emitting element may be provided on an opposite side of the substrate to each microlens and configured to emit radiation through the substrate and through the associated microlens.

In an example embedment, the radiation-emitting elements may be implemented as ‘bottom-emitting’ VCSELs mounted or formed on an opposite side of the substrate to each microlens, wherein each VCSEL is configured to emit a beam of radiation from a ‘bottom surface’ e.g. a surface adjacent the substrate, such that the beam is directed to propagate through the substrate. The substrate may be formed of a material, e.g. GaAs, glass or silicon, which may be substantially transparent to wavelengths of radiation emitted by each radiation-emitting element.

Each microlens may be formed over the corresponding plurality of radiation-emitting elements.

In an example embedment, the radiation-emitting element may be implemented as ‘top-emitting’ VCSELs mounted or formed on that same side of the substrate as each microlens.

The plurality of radiation-emitting elements may be configurable to emit radiation individually and/or in subsets.

That is, each radiation-emitting element or each group or subset of radiation-emitting elements may be addressable. Advantageously, this may enable a single optical device to be configurable to emit radiation in one or more distinct and/or overlapping zones. Characteristics of emitted radiation in each zone may be defined, at least in part, by the above-described offsets of the radiation-emitting elements relative to the center of a corresponding microlens

Each subset of radiation-emitting elements may be arranged relative to the corresponding microlens to provide a different field of illumination.

Advantageously, the disclosed optical device may be particularly suitable for use in multi-zone sensors, wherein the sensor may be required to provide multiple distinct fields of illumination.

The optical device may be formed either as a monolithic chip, or integrated by discrete components. For example, in some embodiments the microlens or plurality of microlenses may be provided as one or more discrete components that are fixed, adhered, or other disposed relative to the plurality of radiation-emitting elements on the substrate.

In some embodiments the microlens or plurality of microlenses. e.g. a microlens array, may be directly etched into the substrate comprising the plurality of radiation-emitting elements. That is, in an example, one or more microlenses may be directly etched into a VCSEL substrate by photolithography process.

According to a second aspect of the disclosure, there is provided a method of manufacturing an optical device. The method comprises providing a plurality of radiation-emitting elements on a substrate. The method comprises arranging a microlens on the substrate such that, in use, a beam of radiation emitted by each of the plurality of radiation-emitting elements propagates through the microlens i.e. is directed through the microlens.

In some embodiments, arranging a microlens on the substrate may comprise forming the microlens on the substrate, such as by nanoimprinting, etching or otherwise.

In some embodiments, arranging a microlens on the substrate may comprise adhering a microlens to the substrate. In an example, a microlens array formed on further substrate may be adhered to, or otherwise positioned relative to, the substrate.

In an example, the microlens may be formed by depositing a thin film of a transparent material onto the surface of the substrate and/or over the plurality of radiation-emitting elements. The transparent material is a material that is transparent to the wavelength of radiation emitted by the plurality of radiation-emitting elements. In some examples, the thin film may be a polymer film deposited by a polymer thin film deposition technique, e.g., by spin coating, roll coating, plasma or vapor deposition, or other thin polymer film deposition technique. The thin film may be cured after deposition. In some examples, the thin film may be an oxide film, such as a silicon oxide film, deposited by a thin film deposition technique such as plasma or vapor deposition. In some examples, the thin film may be processed following deposition to generate a planar surface. One or more microlenses may subsequently be formed in the transparent material using thin film patterning techniques, such as etching, imprinting and/or lithographic techniques. In some examples, portions of the thin film defined by a lithographic process may be melted to form dome-shaped lenses.

In some embodiments, one or more microlenses may be fabricated by a photolithographic process wherein a microlens is first shaped using a grayscale mask or a thermal reflow of photoresist, and subsequently transferred to a chosen microlens material by an etching process.

An offset between each radiation-emitting element and a center of the microlens may be selected such that each beam of radiation is deflected by the microlens at an individually determined angle relative to the substrate surface normal.

That is, each radiation-emitting element may be laterally offset on a plane defined by the substrate. Therefore, radiation emitted by each radiation-emitting element may be incident upon a different portion of a microlens, and therefore an angle of incidence of each beam of radiation with a surface of the microlens upon exiting the microlens may be selected accordingly to define a desired field of illumination.

The method may comprise arranging a plurality of microlenses on the substrate, each microlens having a corresponding plurality of radiation-emitting elements formed or mounted on the substrate such that, in use, a beam of radiation emitted by each radiation-emitting element propagates through a corresponding microlens.

That is, in some embodiments the radiation-emitting elements may be formed in one or more layers on the substrate, such as in one or more epitaxial layers grown on the substrate. In other embodiments, the radiation-emitting elements may be provided as discrete components and surface-mounted on the substrate.

The step of providing a plurality of radiation-emitting elements on the substrate may precede or succeed the step of arranging the microlens on the substrate such that, in use, the beam of radiation emitted by each of the plurality of radiation-emitting elements propagates through the microlens.

According to a third aspect of the disclosure, there is provided a time-of-flight sensor comprising the optical device according to the first aspect.

The time-of-flight sensor may be configured as a multi-zone sensor, wherein each zone may correspond to a subset of the plurality of radiation-emitting elements.

According to a fourth aspect of the disclosure, there is provided a communications device comprising the time-of-flight sensor according to the third aspect.

The communications device may be any of: a mobile computing device; a smartphone; a personal computer; a laptop computer; a tablet device; a smartwatch; a wearable device

In yet further aspects of the disclosure, the optical device may be implemented in a light detection and ranging (LIDAR) device, e.g. to provide an illumination beam for a LiDAR device.

In yet further aspects, the optical device may be implemented in a 3-D imaging system.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF THE DRAWINGS

These and other aspects of the present disclosure will now be described, by way of example only, with reference to the accompanying drawings, wherein:

FIG. 1 depicts a cross-sectional view of a prior art optical device;

FIG. 2 depicts a cross-sectional view of a further prior art optical device;

FIG. 3 depicts a cross-sectional view of an optical device according to an embodiment of the disclosure;

FIG. 4 depicts a cross-sectional view of a further optical device according to an embodiment of the disclosure;

FIG. 5 is a schematic diagram of a top view of an optical device according to an embodiment of the disclosure;

FIG. 6 depicts a plan view of an optical device according to an embodiment of the disclosure, wherein multiple layers of the device are depicted;

FIG. 7 depicts a cross-sectional view of an optical device comprising a plurality of bottom-emitting VCSELs, according to an embodiment of the disclosure;

FIG. 8 depicts a cross-sectional view of an optical device comprising a plurality of top-emitting VCSELs according to an embodiment of the disclosure;

FIG. 9 depicts a time-of-flight sensor according to an aspect of the disclosure;

FIG. 10 depicts a communications device according to an aspect of the disclosure; and

FIG. 11 depicts a method of manufacturing an optical device according to an embodiment of the disclosure.

### DETAILED DESCRIPTION OF THE DRAWINGS

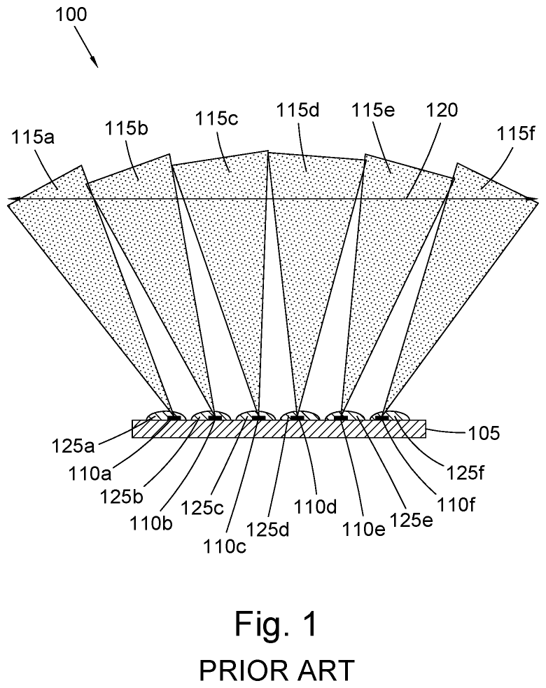

FIG. 1 depicts a cross-sectional view of a prior art optical device 100. The optical device 100 comprises a substrate 105. The substrate 100 may be, for example, a GaAs, glass or silicon substrate.

A plurality of radiation-emitting elements 110a-f are provided on a substrate 105. As an example, the radiation-emitting elements 110a-f may be vertical cavity surface emitting lasers (VCSELs). As such, each radiation-emitting elements 110a-f may be configured to emit a beam 115a-f of radiation.

The beams 115a-f collectively define a field of illumination 120. That is, each beam 115a-f may be combined with adjacent beams 115a-f, such that collectively the optical device 100 emits an overall beam with the field of illumination 120.

The optical device 100 also comprises a plurality of microlenses 125a-f. A microlens 125a-f is associated with each radiation-emitting element 110a-f. In the example of FIG. 1, a microlens 125a-f is formed over each radiation-emitting element 110a-f.

Each microlens 125a-f may deflect the beam 115a-f from a corresponding radiation-emitting element 110a-f. e.g. by refraction within each microlens 125a-f. As such, the overall field of illumination 120 of the optical device 100 is defined by the deflection of individual beams 115a-f by the microlenses 125a-f.

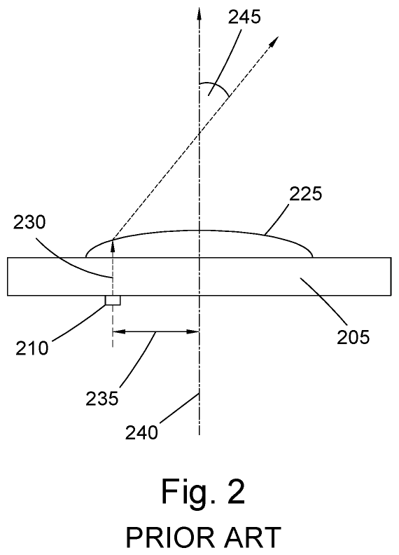

An angle of deflection of each beam 115a-f may be defined by an offset of the radiation-emitting elements 110a-f relative to corresponding microlenses 125a-f. This effect is described in more detail with reference to FIG. 2.

FIG. 2 depicts a cross-sectional view of a further prior art optical device 200. The optical device 200 comprises a radiation-emitting element 210 and an associated microlens 225 disposed on a substrate 205. For purposes of example, only a single radiation-emitting element 210 and corresponding microlens 225 are depicted. It will be appreciated that, in other examples of the optical device, a plurality of radiation-emitting elements 210 and associated microlenses 225 may be provided, as shown in the example of FIG. 1.

As a further example, the radiation-emitting element 210 is depicted as disposed at an opposite side of the substrate 205 to the microlens 225. In the example of FIG. 2, the radiation-emitting element 210 is a bottom-emitting VCSEL, configured to direct a beam 230 of radiation to propagate through the substrate 205 and towards the microlens 225.

The radiation-emitting element 210 is disposed at an offset 235 from a center 240 of the microlens 225.

The microlens 225 is substantially dome-shaped, such that a tangent from an outer surface of the microlens 225 at the center 240 is substantially parallel to a surface of the substrate 205. Since the radiation-emitting element 210 is disposed at an offset 235 from the center 240, the beam 230 of radiation is incident with an outer surface of the microlens 225 at an incident angle defined by a curvature of the outer surface of the microlens 225, e.g. at an angle that is not 0°. That is, the incident angle is defined as the angle between the input beam and the surface normal at the incident point at the boundary, by Snell's Law.

As such, the beam 230 of radiation is deflected by the microlens at an angle 245. The angle 245 is an angle relative to a line normal to the surface of the substrate 205. The angle 245 therefore depends upon the size of the offset 235 and the curvature of the outer surface of the microlens 225. The angle 245 may also depend upon a ratio of a refractive index of the microlens 225 to a surrounding fluid or material. As such, with knowledge of the shape of the microlens 225, a desired angle 245 may be selected by selecting an appropriate size of offset 235.

As described above with reference to FIG. 1, an optical device may comprise a plurality of such microlenses 225 each with a corresponding radiation-emitting element 210. That is, in prior art optical devices, one microlens controls a beam of radiation from a single radiation-emitting element.

However, such optical devices having a plurality of microlenses each with an associated radiation-emitting element may be unduly large, due a relatively large area of the substrate that is required for each microlens. For example, as can be seen in FIG. 2 a diameter of the microlens 225 is significantly larger than the cross section of the radiation-emitting element 210, and hence larger than an aperture of the radiation-emitting element 210. For applications requiring an especially wide angle for a field of illumination, a size of the microlens 225 relative to an aperture of the radiation-emitting element 210 may need to be increased. As such, prior art device, which may comprise in the region of hundreds of radiation-emitting elements 210, may be large.

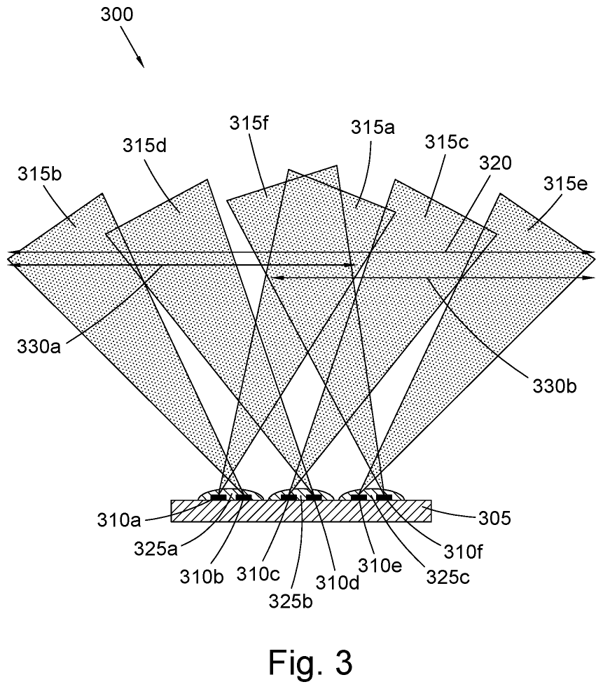

FIG. 3 depicts a cross-sectional view of an optical device 300 according to an embodiment of the disclosure.

A plurality of radiation-emitting elements 310a-f are provided on a substrate 305. As an example, the radiation-emitting elements 310a-f may be VCSELs. As such, each radiation-emitting element 310a-f may be configured to emit a beam 315a-f of radiation.

The beams 315a-f collectively define a field of illumination 320. That is, each beam 315a-f may be combined with other beams 315a-f, such that collectively the optical device 300 emits an overall beam with the field of illumination 320.

The optical device 300 also comprises a plurality of microlenses 325a-c. In the example of FIG. 2, each microlens 325a-c is associated with two radiation-emitting elements 310a-f. In the example of FIG. 3: a first microlens 325a is formed over first and second radiation-emitting elements 310a, 310b; a second microlens 325b is formed over third and fourth radiation-emitting elements 310c, 310d; and a third microlens 325c is formed over fifth and sixth radiation-emitting elements 310c,310f.

The microlenses 325a-c may for example comprise any of: a semiconductor, a dielectric, material, GaAs, Si, SiO₂, TiO₂, polymer, or the like.

It will be appreciated that in other embodiments falling within the scope of the disclosure, different amounts of radiation-emitting elements may be associated with each microlens. For example, in some embodiments, some or all of the microlenses may be associated with fewer than or greater than two radiation-emitting elements.

Each microlens 325a-c may deflect the beams 315a-f from the corresponding radiation-emitting elements 310a-f. e.g. by refraction within each microlens 325a-c. As such, the overall field of illumination 320 of the optical device 300 is defined by the deflection of individual beams 315a-f by the microlenses 325a-c.

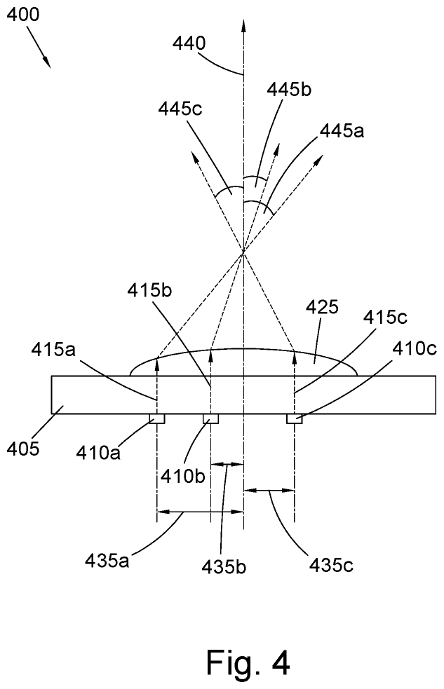

An angle of deflection of each beam 315a-f may be defined by an offset of the radiation-emitting elements 310a-f relative to corresponding microlenses 325a-c. This effect is described in more detail with reference to FIG. 4.

FIG. 4 depicts a cross-sectional view of a further prior art optical device 400. The optical device 400 comprises three radiation-emitting elements 410a-c and an associated microlens 425 disposed on a substrate 405. For purposes of example, only a single microlens 425 with associated radiation-emitting elements 410a-c are depicted. It will be appreciated that, in other examples of the optical device 400, a plurality microlenses 425, each with a plurality of associated radiation-emitting elements 410a-c, may be provided, as shown in the example of FIG. 3.

Furthermore, as a further example, the radiation-emitting elements 410a-c are depicted as disposed at an opposite side of the substrate 405 to the microlens 425. In the example of FIG. 4, the radiation-emitting elements 410a-c are bottom-emitting VCSELs, configured to direct beams 415a-c of radiation to propagate through the substrate 405 and towards the microlens 425.

Each radiation-emitting element 410a-c is disposed at a different offset 435a-c from a center 440 of the microlens 425.

The microlens 425 is substantially dome-shaped, such that a tangent from an outer surface of the microlens 425 at the center 440 is substantially parallel to a surface of the substrate 405. Since the radiation-emitting elements 410a-c are disposed at offsets 435a-c from the center 440, the beams 415a-c of radiation are incident with an outer surface of the microlens 425 at angles defined by a curvature, e.g. a normal, of the outer surface of the microlens 425, e.g. at incident angles that are not 0°.

As such, a first beam 415a of radiation emitted by a first radiation-emitting element 410a is deflected by the microlens 425 at an angle 445a. A second beam 415b of radiation emitted by a second radiation-emitting element 410b is deflected by the microlens 425 at an angle 445b. A third beam 415c of radiation emitted by a third radiation-emitting element 410c is deflected by the microlens 425 at an angle 445c.

The angles 445a-c are angles relative to a line normal to the surface of the substrate 405, e.g. at the center 440. The angles 445a-c therefore depend upon the size of the offsets 435a-c and the curvature of the outer surface of the microlens 425. As such, with knowledge of the shape of the microlens 425, desired angles 445a-c may be selected by selecting appropriate sizes of offsets 435.

As described above with reference to FIG. 3, an optical device 400 may comprise a plurality of such microlenses 425, each with a corresponding plurality of radiation-emitting elements 410a-c. That is, in contrast to prior art optical devices 100 200 wherein one microlens 125a-f, 225 controls a beam of radiation 115a-f, 230 from a single radiation-emitting element 110a-f, 210, for optical devices 300, 400 according to the present disclosure, each microlens 325a-f, 425 controls beams of radiation 315a-f, 415a-c from a plurality of radiation-emitting elements 310a-f. 410a-c.

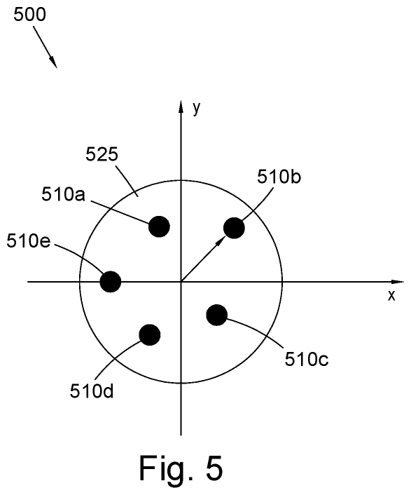

FIG. 5 depicts a schematic diagram of a top view of an optical device 500 according to an embodiment of the disclosure. The optical device 500 comprises a plurality of radiation-emitting elements 510a-c. Also depicted in FIG. 5 is a microlens 525. In the example embodiment, the microlens 525 is substantially circular.

It can be seen that each of the radiation-emitting elements 510a-e is disposed at a different offset relative to a center of the microlens 525. Each offset may be defined by coordinates defining a position of the radiation-emitting elements 510a-c, or at last a radiation-emitting aperture of said radiation-emitting elements 510a-e, relative to a center of the microlens 525.

For example, a first radiation-emitting element 510a is disposed at a position defined by coordinates (Xi, Yi) corresponding to a plane defined by a substrate upon which the first radiation-emitting element 510a is formed or provided, a second radiation-emitting element 510b is disposed at a position defined by coordinates (X2, Y2), and so on. Advantageously, coordinates of radiation-emitting element 510a-e may be selected to define an angle of deflection of a beam of radiation emitted by said radiation-emitting element 510a-e by the microlens 525.

As such, FIG. 5 shows that a plurality of radiation-emitting elements 510a-e may be used with a single microlens 525. With every radiation-emitting element 510a-e being offset differently from the microlens 525, emitted beams of radiation are deflected at different angles and orientations. The offsets (X, Y) may be arranged as per design requirements, for example randomly or regularly. The offsets (X, Y) may be determined from a specified far filed illumination pattern by solving an inverse problem.

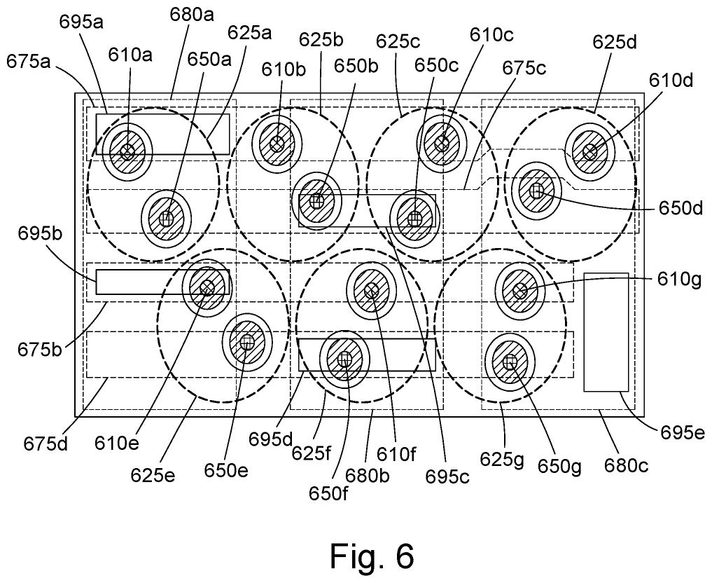

Furthermore, in some embodiments the plurality of radiation-emitting elements 51 Oa-e may be configurable to emit radiation, e.g. addressable, individually or in subsets. For example, in some embodiments a subset of radiation-emitting elements may be arranged relative to the corresponding microlens to provide a different field of illumination. Referring again to FIG. 3, this effect is depicted wherein a first subset of radiation-emitting elements 310a, 310c, 31 Oe emit beams 315a, 315c, 315e that collectively define a first field of illumination 330b, and a second subset of radiation-emitting elements 310b, 31 Od. 31 Of emit beams 315b, 315d, 315f that collectively define a second field of illumination 330a. As such, an optical device according to the disclosure may be particularly suitable for applications requiring multiple illumination zones, such as a multi-zone time-of-flight sensor applications. Addressing subsets of radiation-emitting elements is described in further detail with reference to FIGS. 6 to 8.

FIG. 6 depicts a plan view of an optical device 600 according to an embodiment of the disclosure, wherein multiple layers of the optical device 600 are depicted. The example optical device 600 comprises a substrate having a first subset of radiation-emitting elements 610a-g forming a first zone and a second subset of radiation-emitting elements 650a-g forming a second zone.

As an example, the radiation-emitting elements 610a-g, 650a-g may be VCSELs.

The optical device 600 also comprises a plurality of microlenses 625a-g. In the example of FIG. 6, each microlens 625a-g is associated with a radiation-emitting element 610a-g from the first subset and a radiation-emitting element 650a-g from the second subset.

That is, in the example of FIG. 6: a first microlens 625a is formed over a radiation-emitting element 610a from the first subset and a radiation-emitting element 650a from the second subset; a second microlens 625b is formed over a radiation-emitting element 610b from the first subset and a radiation-emitting element 650b from the second subset; and so on. For purposes of example, each microlens 625a-g is substantially circular in plane view, and arranged in a hexagonal-packing arrangement to minimize a size of the optical device 600.

It can be seen that the radiation-emitting elements 610a-g, 650a-g associated with each microlens 625a-g have different offsets, e.g. different (X, Y) coordinates on a plane parallel to the substrate, relative to a center of said microlens 625a-g.

Each subset of radiation-emitting elements 610a-g, 650a-g is separately addressable, e.g. configurable to be enabled/disabled independently of the other subset. As such, the device 600 may be suitable for applications requiring multiple illumination zones, such as a multi-zone time-of-flight sensor. That is, advantageously the single optical device 600 is configurable to emit radiation in one or more distinct and/or overlapping zones. Characteristics of emitted radiation in each zone may be defined, at least in part, by the above-described offsets of the radiation-emitting elements relative to the center of a corresponding microlens.

Connectivity to each radiation-emitting elements 610a-g. 650a-g is provided through various metal layers. An example configuration is provided in FIG. 6.

In the example of FIG. 6, all radiation-emitting elements in a same row and in a same subset are connected by a trace. For example, a first trace 675a connects radiation-emitting elements 610a, 610b, 610c and 61 Od from the first subset. A second trace 675b connects radiation-emitting elements 61 Oc, 61 Of and 61 Og from the first subset. Both the first trace 675a and the second trace 675b are coupled to a first pad 680a by vias 695a, 695b. As such, the first pad 680a may provide a conductive path to the anodes of all of the radiation-emitting elements 610a-g in the first subset.

A third trace 675c connects radiation-emitting elements 650a. 650b. 650c and 650d from the second subset. A fourth trace 675d connects radiation-emitting elements 650c. 650f and 650g from the second subset. Both the third trace 675c and the fourth trace 675d are coupled to a second pad 680b by vias 695c. 695d. As such, the second pad 680b may provide a conductive path to the anodes of all of the radiation-emitting elements 650a-g in the second subset.

A third pad 680c may be connected by a via 695e to a layer providing connectivity to a cathode of all of the radiation-emitting elements 610a-g. 650a-g.

As such, the optical device 600 may be provided as a surface-mountable device, wherein the third pad 680c provides a common conductive connection to a cathode of all of the radiation-emitting elements 610a-g. 650a-g, and the first pad 680a provides a conductive connection to enable all of the first subset of radiation-emitting elements 610a-g and the second pad 680b provides a conductive connection to separately enable all of the second subset of radiation-emitting elements 650a-g.

In embodiments falling within the scope of the disclosure, the electrode polarity of 680a-b and 680c may be switched depending upon a design of the device.

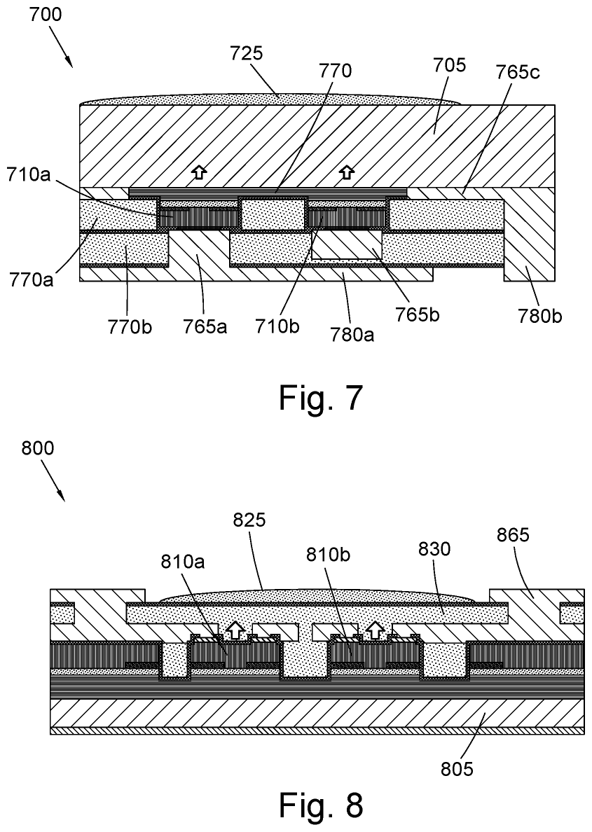

Such a configuration is illustrated in cross section in FIG. 7, which depicts a cross-sectional view of an optical device 700 comprising a plurality of radiation-emitting elements 710a-b according to an embodiment of the disclosure. In the example of FIG. 7, the radiation-emitting elements 710a-b are bottom-emitting VCSELs, and are configured to emit radiation through a substrate 705. A microlens 725 is provided on an opposite side of the substrate 705 to the radiation-emitting elements 710a-b. As such, radiation emitted by the radiation-emitting elements 710a-b is directed through. e.g. propagates through, the microlens 725.

Similar to the optical device of FIG. 6, the optical device 700 comprises a first pad 780a coupled to an anode of a first radiation-emitting element 710a by a conductive element 765a. In this example, the first radiation-emitting element 710a is part of a first subset of radiation-emitting elements, wherein other radiation-emitting elements in the first subset are not shown for purposes of simplicity of illustration.

In this example, the second radiation-emitting element 710b is part of a second subset of radiation-emitting elements, where again for purposes of simplicity of illustration only a single radiation-emitting element 710b is depicted. An anode of the second radiation-emitting element 710b is coupled to a conductive element 765b which may provide connectivity to a second pad (not shown), thereby enabling the first and second subsets to be separately controlled, as described above with reference to the embodiment of FIG. 6.

In this example, each radiation-emitting element 710a. 710b comprises a p-doped Distributed Bragg Reflector (pDBR) and an n-doped DBR (nDBR) 770 and an active region disposed between the pDBR and nDBR in a laser cavity. In the example arrangement, the nDBR is shared by the radiation-emitting elements 710a. 710b. The nDBR is coupled to a third pad 780b by one or more conductive elements 765c. e.g. a metal trace and/or via. As such, the third pad 780b is effectively coupled to a cathode of both radiation-emitting elements 710a. 710b.

In the example of FIG. 7, polymer and/or dielectric layers may be implemented between metal layers, which may provide both electrical insulation between components and planarization of layers. That is, such polymer and/or dielectric layers may fill a spacing between mesas of the radiation-emitting elements 710a. 710b, and a spacing between conductive elements such as traces and/or vias to provide a planar surface level for the pads 780a, 780b.

FIG. 8 depicts a cross-sectional view of an optical device 800 according to an embodiment of the disclosure. In contrast to the embodiment of FIG. 7 wherein the radiation-emitting elements 810a-b are bottom-emitting VCSELs, in the example of FIG. 8 a first radiation-emitting element 810a and a second radiation-emitting element 810b are top-emitting VCSELs.

The radiation-emitting elements 810a-b are provided on a substrate 805. Electrical connectivity to the radiation-emitting elements 810a-b is provide through conductive elements 865, which may comprise one or more electrical traces, vias contacts and/or pads. A planarization layer 830, which may for example comprise polymer and/or dielectric layers, is formed over the conductive elements 865 to provide a planar surface for arranging a microlens 825.

The microlens 825 is arranged on the substrate, e.g. on the planarization layer. Similar to the embodiment of FIG. 7, both radiation-emitting elements 810a-b are configured to emit radiation through the microlens 825.

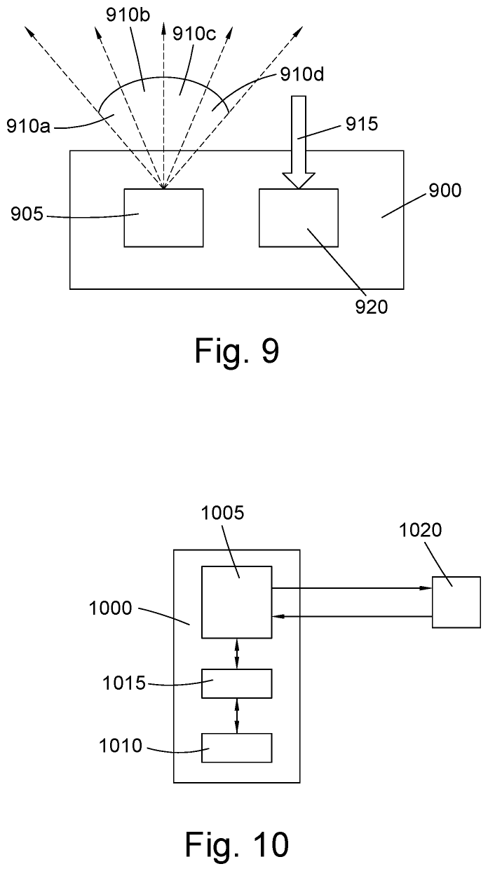

FIG. 9 depicts a time-of-flight 900 sensor according to an aspect of the disclosure. The time of flight sensor comprises an optical device 905, which may be an optical device corresponding to the embodiments of FIGS. 3 to 8. That is, the optical device 905 comprises a plurality of radiation-emitting elements provided on a substrate; and a plurality of microlenses arranged on the substrate, each microlens having a corresponding plurality of radiation-emitting elements arranged on the substrate such that a beam of radiation emitted by each radiation-emitting element propagates through a corresponding microlens.

As described above, the radiation-emitting elements of the optical device 905 may be operated in subsets, wherein each subset corresponds to a zone, e.g. a particular field of illumination. For purposes of example only, the optical device 905 provides four zones 910a-d. The time-of-flight sensor 900 also comprises a radiation-sensitive device 920 which is configured to sense radiation 915 emitted by the optical device 905 and reflected by a target.

FIG. 10 depicts a communications device 1000 according to an aspect of the disclosure. For purposes of example, the communications device 1000 is a smartphone. In other examples, the communications device may be a mobile computing device, a personal computer, a laptop computer, a tablet device, a smartwatch, or a wearable device.

The communications device 1000 comprises a time-of-flight sensor 1005. The time-of-flight sensor 1005 may be a sensor as depicted in FIG. 9. The communications device also comprises a camera 1010. The time-of-flight sensor 1005 and the camera are coupled to processing means 1015, which may comprise one or more processors, ASICs, FPGAs and/or microcontrollers.

In an example use, the processing means 1015 may control the time-of-flight sensor 1005 to measure a distance to a target 1020, and then adapt properties such as a focus of the camera 1010 in response to a determined distance. In another example use, the processing means 1015 may control the time-of-flight sensor 1005 to measure a distance to a target, and then adapt properties of an image captured by the camera 1010 in response to a determined distance.

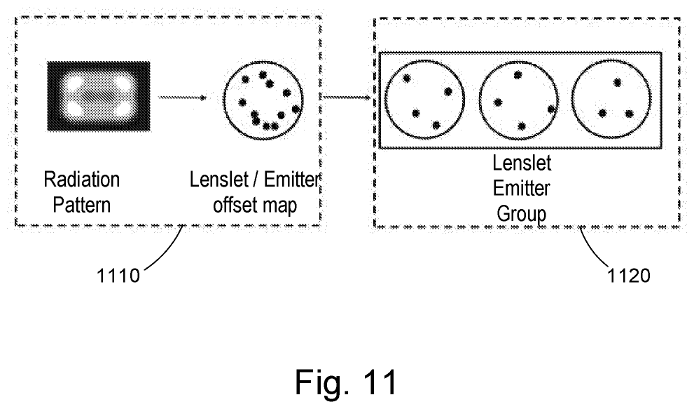

FIG. 11 depicts a method of manufacturing an optical device 300, 400, 500, 600, 700, 800.

In a first step 1110 the method comprises selecting an offset between each radiation-emitting element of a plurality of radiation-emitting elements and a center of a microlens such that a beam of radiation emitted by each radiation-emitting element is deflected by the microlens at an individually determined angle relative to the substrate surface normal. A value of each offset may be determined by a radiation pattern to be achieved. The first step 1110 may comprise providing the radiation-emitting elements on a substrate, wherein a relative position of each radiation-emitting element is defined by the selected offsets.

In a second step 1120, the method comprises arranging one or more microlenses on the substrate such that the spacing of each radiation-emitting element is within a fabrication process limitation, e.g. adequate spacing is provided between neighboring radiation-emitting lenses. That is, one or more microlenses are arranged on the substrate such that, in use, a beam of radiation emitted by each of the plurality of radiation-emitting elements propagates through a corresponding microlens i.e. is directed through the microlens.

Continuing with the example of FIG. 1, in the first step 1110 relative offsets of eleven radiating-emitting elements are selected based on the desired radiation pattern. In step 1120, three microlenses are depicted, each having associated subset of the 11 radiation-emitting elements.

It will be understood that the above description is merely provided by way of example, and that the present disclosure may include any feature or combination of features described herein either implicitly or explicitly of any generalisation thereof, without limitation to the scope of any definitions set out above. It will further be understood that various modifications may be made within the scope of the disclosure.

LIST OF REFERENCE NUMERALS

| | | | |
|---|---|---|---|
| 100 | Optical device | 510a-e | radiation-emitting |
| 105 | substrate | | elements |
| 110a-f | radiation-emitting | 525 | microlens |
| | elements | 600 | optical device |
| 115a-f | beams | 610a-g | radiation-emitting |
| 120 | field of illumination | | elements |
| 125a-f | microlenses | 625a-g | microlens |
| 200 | optical device | 650a-g | radiation-emitting |
| 205 | substrate | | elements |
| 210 | radiation-emitting | 675a-d | trace |
| | element | 680a-c | pad |
| 225 | microlens | 695a-e | vias |
| 230 | beams | 700 | optical device |
| 235 | offset | 705 | substrate |
| 240 | center | 710 | radiation-emitting |
| 245 | angle | | elements |
| 300 | optical device | 725 | microlens |
| 305 | substrate | 765a-c | conductive elements |
| 310a-f | radiation-emitting | 770 | nDBR |
| | elements | 780a-b | pad |
| 315a-f | beams | 800 | optical device |
| 320 | field of illumination | 805 | substrate |
| 325a-c | microlenses | 810a-b | radiation-emitting |
| 330a-b | field of illumination | | elements |
| 400 | optical device | 825 | microlens |
| 405 | substrate | 830 | planarization layer |
| 410a-c | radiation-emitting | 865 | conductive elements |
| | elements | 900 | time-of-flight sensor |
| 415a-c | beams | 905 | optical device |
| 425 | microlens | 910a-d | zones |
| 435a-c | offsets | 915 | radiation |
| 440 | center | 920 | radiation-sensitive |
| | | | device |
| 445a-c | angle | 1000 | communications device |
| 500 | optical device | 1005 | time-of-flight sensor |
| 1010 | camera | 1110 | first step |
| 1015 | processing means | 1120 | second step. |
| 1020 | target | | |

1. An optical device comprising:
a plurality of radiation-emitting elements provided on a substrate; and
a microlens arranged on the substrate such that a beam of radiation emitted by each of the plurality of radiation-emitting elements propagates through the microlens.

2. The optical device of claim 1, wherein the microlens is configured to deflect the beam of radiation emitted by each of the plurality of radiation-emitting elements at a different angle relative to the substrate.

3. The optical device of claim 1, wherein each radiation-emitting element of the plurality of radiation-emitting elements is disposed at a different offset relative to a center of the microlens.

4. The optical device of claim 1, wherein the plurality of radiation-emitting elements comprises vertical cavity surface emitting lasers formed or mounted on the substrate.

5. The optical device of claim 1, further comprising a plurality of microlenses arranged on the substrate, each microlens having a corresponding plurality of radiation-emitting elements arranged on the substrate such that a beam of radiation emitted by each radiation-emitting element propagates through a corresponding microlens.

6. The optical device of claim 5, wherein:
the plurality of microlenses are implemented as a monolithic microlens array; and/or
the plurality of microlenses are directly etched into the substrate.

7. The optical device of claim 5, wherein each radiation-emitting element is provided on an opposite side of the substrate to each microlens and configured to emit radiation through the substrate and through the associated microlens.

8. The optical device of claim 5, wherein each microlens is formed over the corresponding plurality of radiation-emitting elements.

9. The optical device of claim 5, wherein the plurality of radiation-emitting elements are configurable to emit radiation individually or in subsets.

10. The optical device of claim 9, wherein each subset of radiation-emitting elements is arranged relative to the corresponding microlens to provide a different field of illumination.

11. A method of manufacturing an optical device, the method comprising:
providing a plurality of radiation-emitting elements on a substrate; and
arranging a microlens on the substrate such that, in use, a beam of radiation emitted by each of the plurality of radiation-emitting elements propagates through the microlens.

12. The method of claim 11,
wherein an offset between each radiation-emitting element and a center of the microlens is selected such that each beam of radiation is deflected by the microlens at an individually determined angle relative to the substrate surface normal.

13. The method of claim 11, further comprising,
arranging a plurality of microlenses on the substrate, each microlens having a corresponding plurality of radiation-emitting elements formed or mounted on the substrate such that, in use, a beam of radiation emitted by each radiation-emitting element propagates through a corresponding microlens.

14. A time-of-flight sensor comprising the optical device of claim 1.

15. The time-of-flight sensor of claim 14, configured as a multi-zone sensor, wherein each zone corresponds to a subset of the plurality of radiation-emitting elements.

16. A communications device comprising the time-of-flight sensor of claim 14.
